(19) United States
(12) Patent Application Publication
(10) Pub. No.: US 2021/0335627 A1
(43) Pub. Date: Oct. 28, 2021

(54) BACKSIDE INTERCONNECT FOR INTEGRATED CIRCUIT PACKAGE INTERPOSER

(71) Applicant: Microchip Technology Incorporated, Chandler, AZ (US)

(72) Inventors: Justin Sato, West Linn, OR (US); Yaojian Leng, Portland, OR (US); Bomy Chen, Newark, CA (US); Chris Sundahl, Gresham, OR (US)

(73) Assignee: Microchip Technology Incorporated, Chandler, AZ (US)

(21) Appl. No.: 17/111,973

(22) Filed: Dec. 4, 2020

Related U.S. Application Data
(60) Provisional application No. 63/014,667, filed on Apr. 23, 2020.

(51) Int. Cl. H01L 21/48; H01L 23/498; H01L 21/56

(52) U.S. Cl. CPC H01L 21/4857; H01L 23/49811; H01L 23/49827; H01L 21/486; H01L 21/4853; H01L 21/568; H01L 23/49822

(57) ABSTRACT

Methods are provided for forming an integrated circuit (IC) package interposer configured for back-side attachment. A porous silicon double layer is formed on a bulk silicon wafer, e.g., using a controlled anodization, the porous silicon double layer including two porous silicon layers having different porosities. An interposer is formed over the porous silicon double layer, the interposer including back-side contacts, front-side contacts, and conductive structures (e.g., vias and metal interconnect) extending through the interposer to connect selected back-side contacts with selected front-side contacts. The structure is then split at the interface between the first and second porous silicon layers of the silicon double layer, and the interposer including the second porous silicon layers is inverted and etched to remove the second silicon layer and expose the back-side contacts, such that the exposed back-side contacts can be used for back-side attachment of the interposer to a package substrate or other structure.

### RELATED APPLICATION

This application claims priority to commonly owned U.S. Provisional Patent Application No. 63/014,667 filed Apr. 23, 2020, the entire contents of which are hereby incorporated by reference for all purposes.

### TECHNICAL FIELD

The present disclosure relates to integrate circuit (IC) packages, and more particularly to systems and methods for backside bonding/interconnect for an IC package interposer, e.g., formed without through-silicon-vias (TSVs).

### BACKGROUND

The concept of Moore's law has largely shifted from pure-silicon (Si) process integration to die-assembly and heterogeneous die integration (i.e., a shift from cost-per-transistor to cost-per-packaged transistor), for example to provide total-system-solutions (TSS) in a single package. One example of a heterogeneous die integration is a multi-die package assembly including multiple different types of dies mounted in a common package. Some heterogeneous multi-die packages are formed as 3-Dimensional and 2.5-D products including multiple dies mounted in a horizontal (flat) orientation on a package substrate, which package substrate in turn may be mounted on a printed circuit board (PCB). In some packages, multiple dies are connected to each other by interconnects formed in an “interposer” structure provided between the dies and the multi-die package substrate. For example, FIG. 1 shows a cross-section of an example multi-die FPGA package 50 by Xilinx, Inc. and Taiwan Semiconductor Manufacturing Company Limited (TSMC).

The cross-sectional view of FPGA package 50 shows an FPGA die 52 and a memory die 54 solder mounted on a silicon interposer 56, which is in turn solder mounted on a package substrate 58. The silicon interposer 56 includes (a) interconnections 60 between FPGA 52 and memory 54 (and similar interconnections between other dies mounted on the silicon interposer 56), and (b) “through-silicon vias” (TSVs) 62 extending vertically through the interposer 56 to connect the FPGA 52 and memory 54 to the package substrate 58 (and to electronics on a PCB to which the multi-die FPGA package 50 is mounted through TSVs or other connections (not shown) extending vertically though the package substrate 58).

The TSVs 62 provide a backside interconnect of the interposer 56 to the package substrate 58. TSV backside interconnect constructions are typically expensive and subject to processing limitations and interconnect pitch limitations.

An alternative to a TSV backside interconnect construction is front-side (top-side) wire bonding of the interconnect down to the package substrate. For example, FIGS. 2A and 2B illustrate an example top three-dimensional view and an example side view, respectively, of an example mixed-orientation multi-die (“MOMD”) package 100. The example MOMD package 100 includes a plurality of dies 102 mounted on a horizontally-extending interposer (or “die mount base”) 104. The plurality of dies 102 mounted on the horizontally-extending interposer 104 may include multiple different types of dies, and one or more instance of each type of die. In addition, the plurality of dies 102 may be mounted on the horizontally-extending interposer 104 in at least two different orientations, to define a “mixed-orientation” package. For example, as shown, MOMD package 100 may include both (a) one or more dies 110 mounted horizontally as horizontally-mounted dies or “HMDs” and (b) one or more dies 112 mounted vertically as vertically-mounted dies or “VMDs.” The example MOMD package 100 shown in FIGS. 2A and 2B includes (a) two HMDs 110a and 110b and (b) four VMDs 112a, 112b, 112c, and 112d, all mounted to an interposer 104. The terms “die” and “chip” are used interchangeably herein.

The interposer 104 is front-side mounted on a package substrate 106 by wire bond connections 120, and the package substrate 106 may be mounted to a PCB or other structure, e.g., by solder connections. The various dies 102 mounted on the horizontally-extending interposer 104 may be connected to each other by conductive interconnects formed in the horizontally-extending interposer 104, and connected to the underlying PCB (or other device to which the package substrate 106 is mounted) via the wire bond connections 120 and conductors 122 extending vertically through the package substrate 106. MOMD package 100 is described in further detail in co-pending U.S. patent application Ser. No. 16/540,117 filed Aug. 14, 2019 and entitled “Mixed-Orientation Multi-Die Integrated Circuit Package with at least one Vertically-Mounted Die,” the entire contents of which application are hereby incorporated by reference for all purposes. Wire bonding, e.g., as provided in the illustrated MOMD package 100, is a mature technology, but often subject to resistance and inductance related issues, as well as latency issues associated with die-to-die interconnect.

### SUMMARY OF THE INVENTION

Embodiments of the present invention provide IC devices, and methods of forming IC devices, configured for backside bonding or interconnect between an interposer and package substrate (or other structure). For example, some embodiments provide an interposer configured for backside attach for solder-ball (flip-chip style) or direct bonding (e.g., for advanced applications), as opposed to conventional through-silicon-via (TSV) or wire-bond connections. Some embodiments provide sub-micron backside interconnect between an interposer and package substrate, as opposed to much larger and more expensive TSV connections. In some embodiments, the backside interconnect between an interposer and package substrate enables a higher pin count per area (e.g., pins/mm²) than conventional attachment designs, e.g., TSV and wire-bonding. Some embodiments provide thousands or tens of thousands of low-latency backside interconnects in an IC package.

One aspect provides a method of forming an integrated circuit (IC) package interposer configured for back-side attachment. The method includes forming a base silicon wafer including a porous silicon double layer over a bulk silicon region, the porous silicon double layer including a first porous silicon layer having a first porosity adjacent a second porous silicon layer having a second porosity different than the first porosity. The method further includes forming an interposer over the porous silicon double layer, including (a) back-side contacts on a back side of the interposer, (b) front-side contacts on a front side of the interposer, and (c) conductive structures extending through a vertical thickness of the interposer to connect selected back-side contacts with selected front-side contacts. The method further includes splitting the porous silicon double layer to separate the first porous silicon layer from the second porous silicon layer, removing the separated first porous silicon layer and bulk silicon region, and removing at least the second silicon layer to expose the back-side contacts, the exposed back-side contacts configured for attachment to a package substrate or other structure.

In one embodiment, the method includes using the exposed back-side contacts to back-side mount the IC package interposer to the package substrate or other structure.

In one embodiment, the method includes soldering the exposed back-side contacts to the package substrate or other structure.

In one embodiment, the method includes direct attaching the exposed back-side contacts to the package substrate or other structure.

In one embodiment, the method includes mounting at least one die to at least one front-side contact. In one embodiment, the method includes mounting the at least one die to the at least one front-side contact and encapsulating the at least one mounted die prior to splitting the porous silicon double layer. In one embodiment, the method includes mounting the at least one die to the at least one front-side contact after splitting the porous silicon double layer. In one embodiment, the method includes mounting at least one die to at least one front-side VMD contact in a vertical orientation and mounting at least one die to at least one front-side HMD contact in a horizontal orientation.

In one embodiment, splitting the porous silicon double layer to separate the first porous silicon layer from the second porous silicon layer comprises using a water jet to separate the first porous silicon layer from the second porous silicon layer.

In one embodiment, the removing at least the second silicon layer after splitting the porous silicon double layer comprises etching the second silicon layer to expose the back-side contacts.

In one embodiment, forming the interposer comprises forming a plurality of vias and at least one metal layer between the back-side contacts and front-side contacts to define conductive connections between the back-side contacts and front-side contacts.

Another aspect provides a method of forming an integrated circuit (IC) package interposer configured for back-side attachment. An anodizing process is performed on a base silicon wafer to form a multi-layer silicon region including a first porous silicon layer having a first porosity adjacent a second porous silicon layer having a second porosity different than the first porosity. An interposer is formed over the multi-layer silicon region, the interposer including back-side contacts on a back side of the interposer, front-side contacts on a front side of the interposer, and conductive structures extending through a vertical thickness of the interposer to connect selected back-side contacts with selected front-side contacts. At least one die is mounted to at least one of the front-side contacts. The multi-layer silicon region is split to separate the first porous silicon layer from the second porous silicon layer. After splitting the multi-layer silicon region, at least the second silicon layer is removed to expose the back-side contacts, the exposed back-side contacts configured for attachment to a package substrate or other structure.

In one embodiment, mounting at least one die to at least one of the front-side contacts comprises mounting at least one die to at least one front-side VMD contact in a vertical orientation and mounting at least one die to at least one front-side HMD contact in a horizontal orientation.

Another aspect provides an integrated circuit (IC) package, including an IC package substrate and an interposer. The interposer includes back-side contact pads on a back side of the interposer, front-side contact pads on a front side of the interposer, and conductive structures extending through a vertical thickness of the interposer to connect selected back-side contact pads with selected front-side contact pads. At least one die is mounted to the front-side contact pads. The interposer is back-side attached to an IC package substrate by the back-side contact pads.

In some embodiments, the interposer includes no wafer substrate, and no through-silicon vias (TSVs), unlike conventional IC package interposers.

### BRIEF DESCRIPTION OF THE FIGURES

FIG. 1 shows a cross-section of an example conventional FPGA package including multiple semiconductor dies mounted on an interposer including through-silicon vias connecting the dies to an underlying package substrate;

FIGS. 2A and 2B illustrate a three-dimensional top view and a side view, respectively, of an example known mixed-orientation multi-die (MOMD) package including both (a) horizontally-mounted dies (HMDs) and (b) vertically-mounted dies (VMDs);

FIG. 3 illustrates a known ELTRAN® (Epitaxial Layer Transfer) process for splitting a semiconductor structure at a porous silicon interface, e.g., using a water jet;

FIGS. 4A-4P illustrate an example method for constructing an IC package interposer configured for back-side attachment to a package substrate, without TSV or wire-bonding connection between the interposer and package substrate, according to one example embodiment of the invention;

FIGS. 5A-5Q illustrates an example process for constructing an example MOMD package interposer configured for back-side attachment to a package substrate, without TSV or wire-bonding connection between the interposer and package substrate, according to one example embodiment; and

FIGS. 6A-6B illustrate an alternative to the process shown in FIGS. 5A-5Q, wherein voids are formed in back-side contact pads, which may facilitate solder-ball attachment or direct attachment of the contact pads to a package substrate, according to one example embodiment.

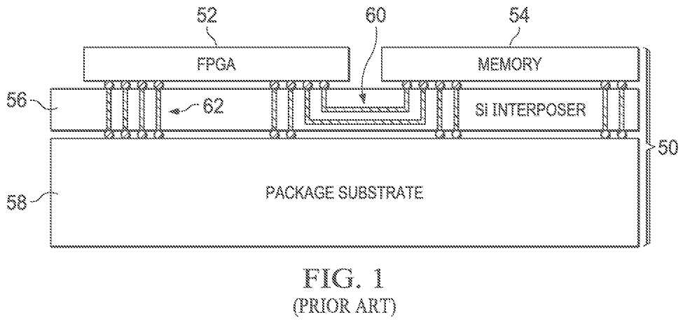

### DETAILED DESCRIPTION

Embodiments of the present invention provide IC devices, and methods of forming IC devices, configured for backside bonding/interconnect between an interposer and package substrate (or other structure). For example, some embodiments provide an interposer configured for backside attach for solder-ball (flip-chip style) or direct bonding (e.g., for advanced applications), as opposed to conventional through-silicon-via (TSV) or wire-bond connections. Some embodiments provide sub-micron backside interconnect between an interposer and package substrate, as opposed to much larger and more expensive TSV connections. In some embodiments, the backside interconnect between an interposer and package substrate enables a higher pin count per area (e.g., pins/mm²) than conventional attachment designs, e.g., TSV and wire-bonding. Some embodiments provide thousands or tens of thousands of low-latency backside interconnects in an IC package.

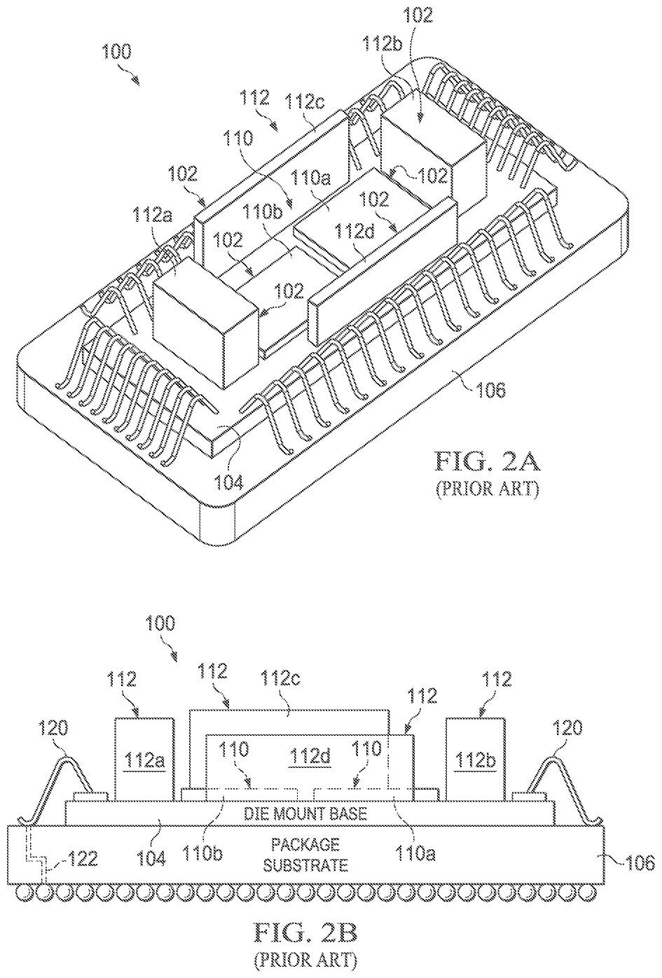

Some embodiments provide an MOMD package having an interposer configured for backside attachment (also referred to as “backside attach” or “backside mounting”) to a package substrate, for example a modified construction of MOMD package 100 shown in FIGS. 2A-2B discussed above, in which the interposer 104 is configured for backside attach to the package substrate 106, e.g., by solder-ball or direct bonding, as opposed to front-side wire bonding.

Some embodiments provide a method of forming an interposer configured for backside attach, in which the method utilizes encapsulation (temporary or permanent) to provide structural integrity, in place of a carrier wafer. In some embodiments the method includes performing die-to-wafer bonding, and then performing a wafer dicing.

Some embodiments involve constructing an interposer on a silicon wafer and utilizing a wafer splitting process to remove a bulk silicon portion of the wafer, which may be followed by etching or other suitable material removal techniques to expose back-side (bottom-side) contacts (e.g., conductive pads) of the interposer. The exposed contacts may then be used to backside attach the interposer to a package substrate or other structure. Depending on the particular embodiment or implementation, one or more dies may be mounted to the interposer (and/or encapsulated in mold compound) before or after the wafer splitting process, or before or after mounting the interposer to the package substrate or other structure.

Some embodiments allow for ultra-tight pitch backside interconnect on an interposer without through-silicon-vias for heterogeneous die integration.

In some embodiments, the wafer splitting process may incorporate aspects of ELTRAN® (Epitaxial Layer Transfer) silicon-on-insulator (SOI) technology developed by Canon, Inc. For example, some embodiments provide a method including constructing a base wafer with a double-layer porous silicon (Si) region, followed by forming back-side conductive pads on the porous Si region and mounting die(s) (directly or indirectly) to the back-side pads, followed by splitting the porous Si layer using a water-jet to split the wafer and etching/removing remaining porous Si to expose the back-side pads. The package may then be backside mounted to a substrate or other structure using the back-side pads, e.g., by solder-ball attachment or direct bonding.

In some embodiments, stress relief structures may be built in the interposer with at least partially open voids, i.e., not completely filled by inter-metal dielectric (IMD). Further, in some embodiments, voids may be created in back-side metal contact pads to assist with soldering and/or direct attach of the interposer to another device.

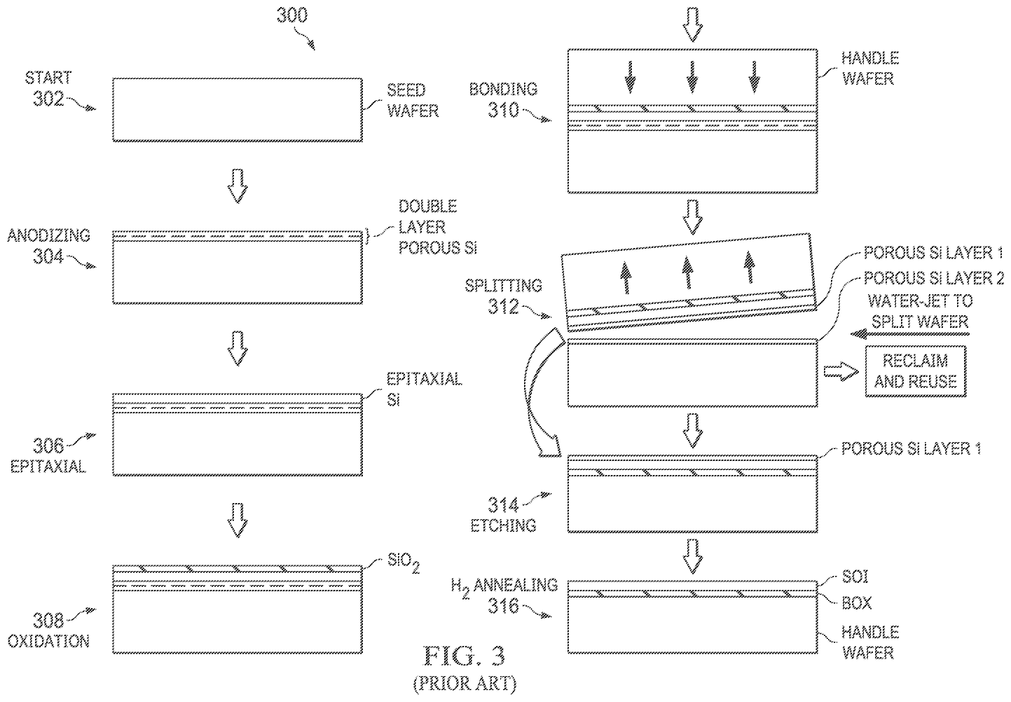

FIG. 3 illustrates a known process 300 developed by Canon, Inc, known commercially as the ELTRAN® process 300. A seed wafer is provided at 302. A double layer porous Si layer is formed on the seed wafer at 304, e.g., by a controlled anodization process. In one implementation, the anodization involves passing a current through a solution of HF and ethanol with the single-crystal seed wafer 302 as the anode to form microscopic pores of a few nm in diameter on the surface of the single-crystal seed wafer at a density of about 10¹¹/cm². The current density may be varied to create a porous layer that has a dual-layered (or other multi-layered) structure, i.e. a porous Si double layer. In one implementation, a first layer of porous Si closes to the surface of the single-crystal seed wafer is formed using a low current density, after which the current density is raised to form a second porous Si layer of different porosity below the first layer. For example, the second porous Si layer may contain pores with diameters 2-3 times greater than the first porous Si layer. The physical interface (planar interface) between the first and second porous Si layers has elevated stresses due to the different porosities at the interface.

An epitaxial Si film is grown on the porous Si double layer at 306, and oxidized to form a silicon oxide (SiO₂) layer at 308. A handle Si wafer is bonded to the top of the wafer at 310. The wafer structure is then split at the porous Si double layer at 312, e.g., using a water-jet to split the wafer at the interface between the first and second porous Si layers. At 314, the handle wafer including the first porous Si layer of the porous Si double layer is flipped over, such that the first porous Si layer is on top. An etch is performed to remove the first porous Si layer and expose the underlying epitaxial (SOI) film. The wafer may be annealed at 316, e.g., by hydrogen (H₂) annealing. The original seed wafer (including the second porous Si layer) split from the handle wafer at 312 may be reclaimed and reused.

Some embodiments of the present invention may incorporate any selected steps or aspects of the process 300 shown in FIG. 3, or a similar process. For example, some embodiments may incorporate the process steps beginning at 304, i.e., formation of a double layer porous Si layer having first and second Si layers of different porosity. Additional details of process 300 are described in the paper “ELTRAN® (SOI-Epi Wafer™) Technology” by Yonehara and Sakaguchi, published in Progress in SOI Structures and Devices Operating at Extreme Conditions, pp. 39-86, 2002, available at https.//doi.org/10.1007/978-94-010-0339-1, the entire contents of which paper are hereby incorporated by reference for all purposes.

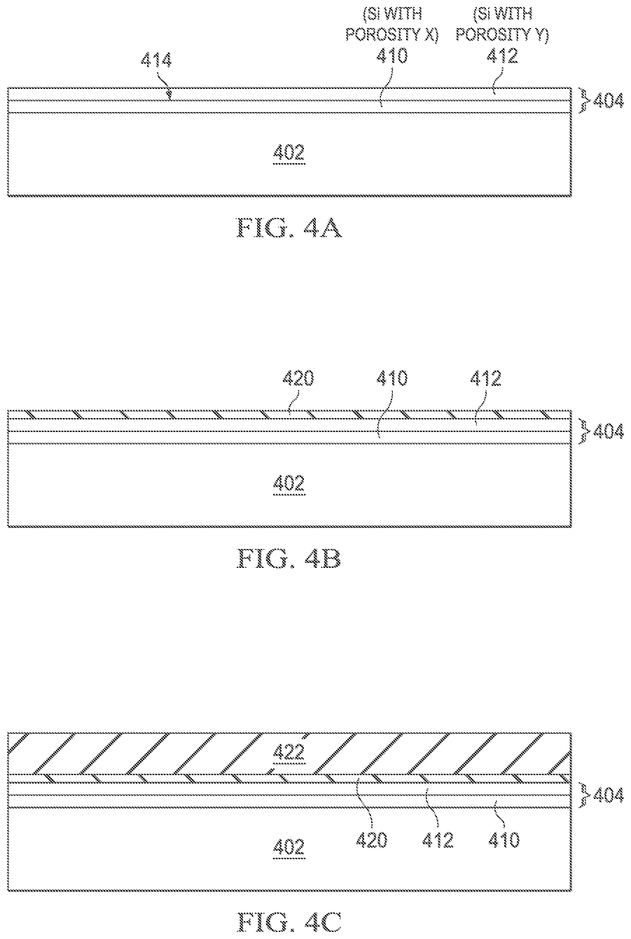

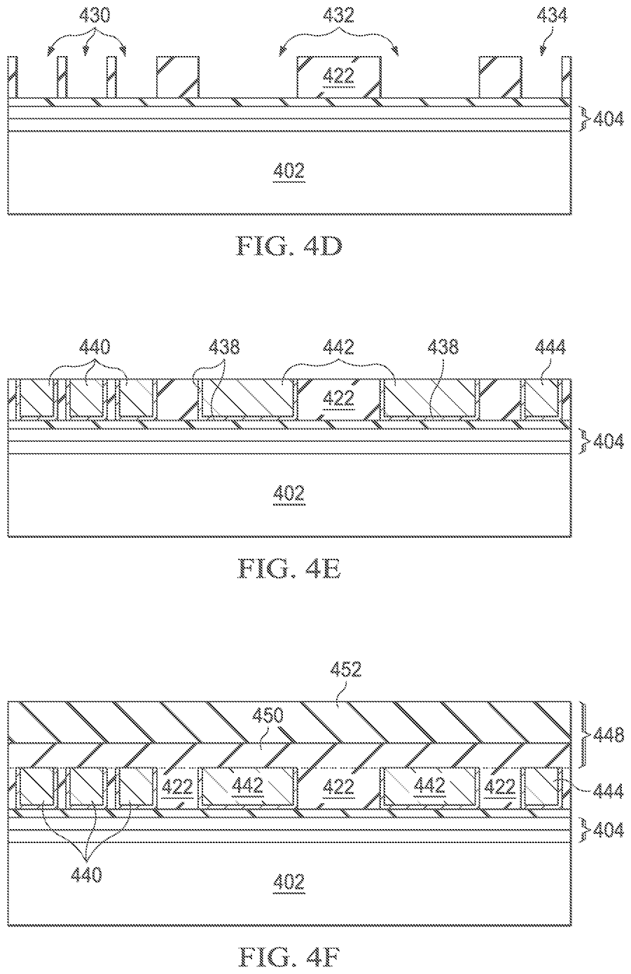

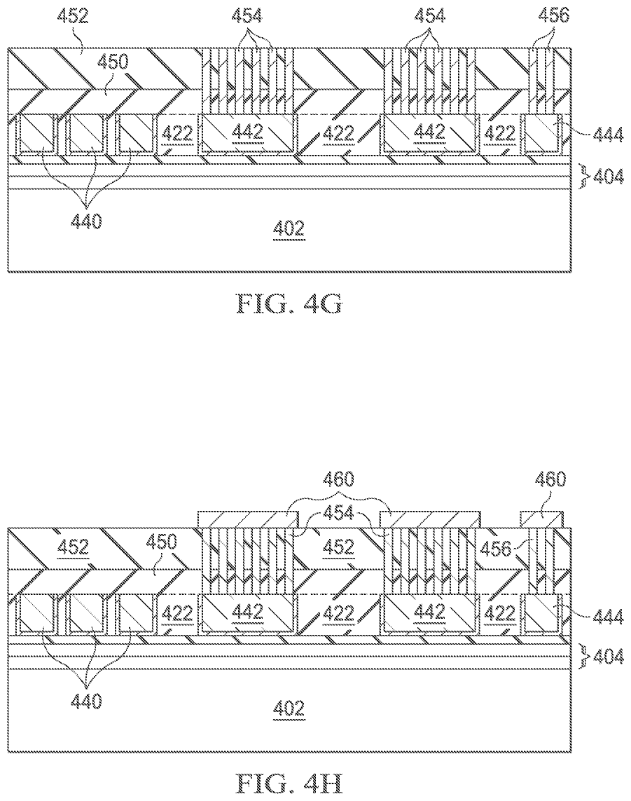

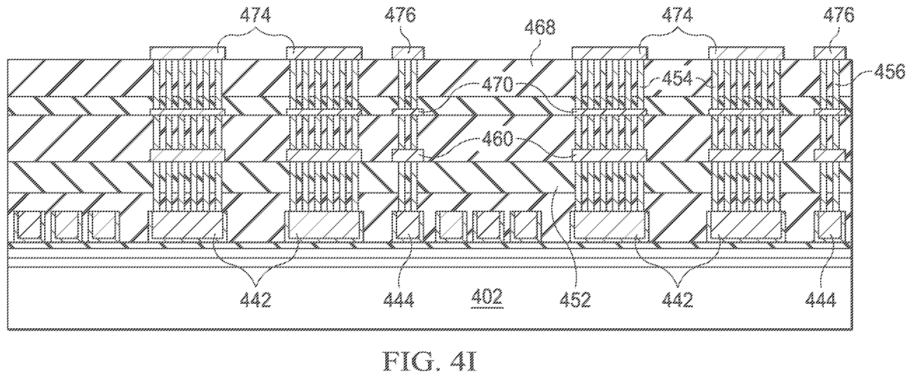

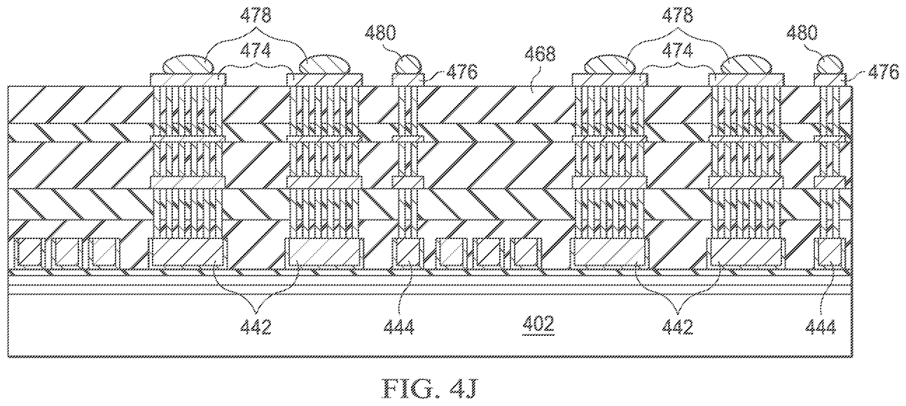

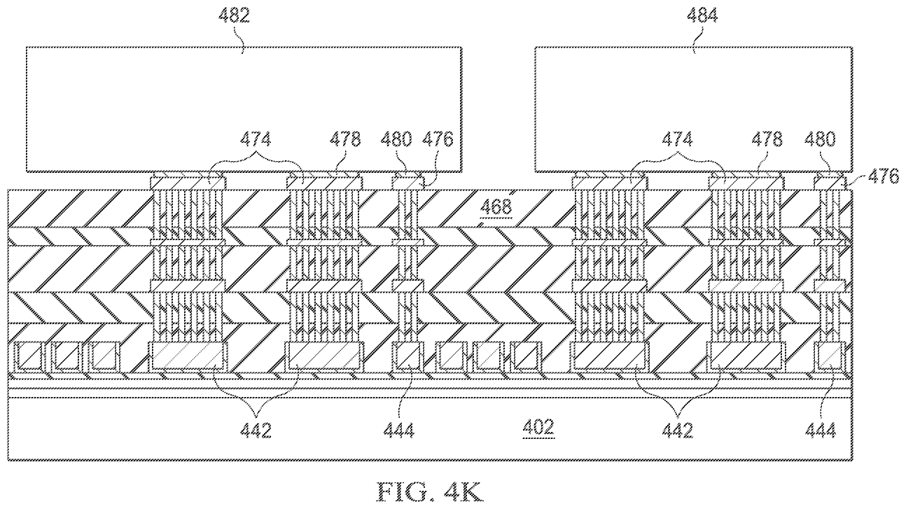

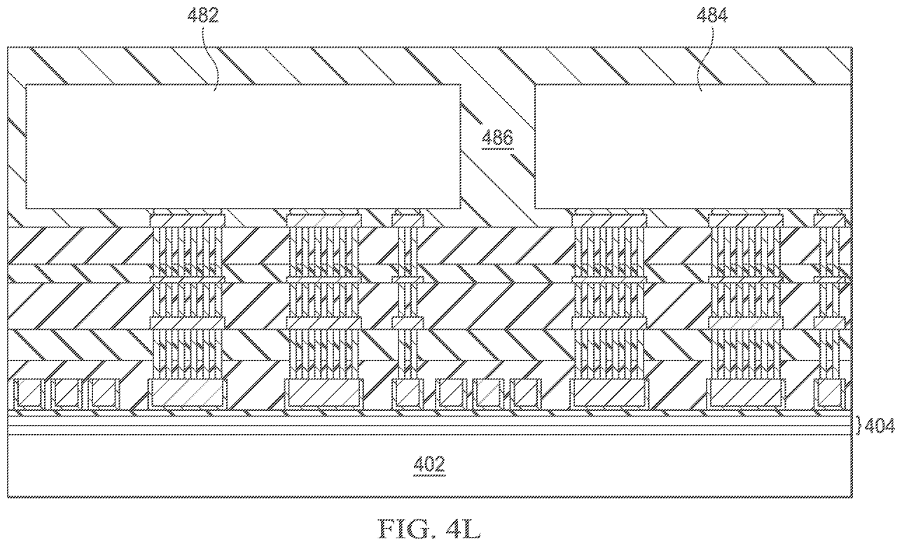

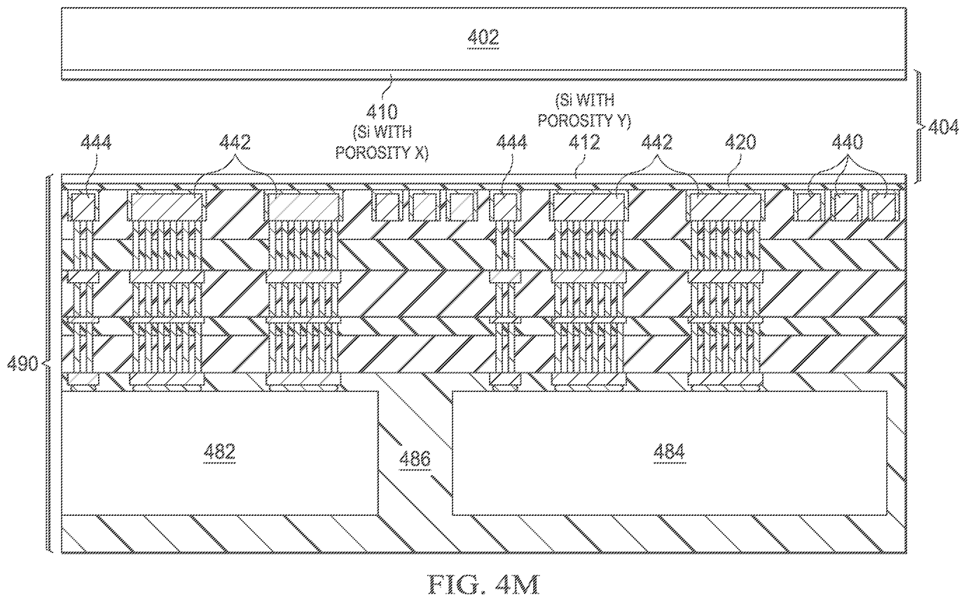

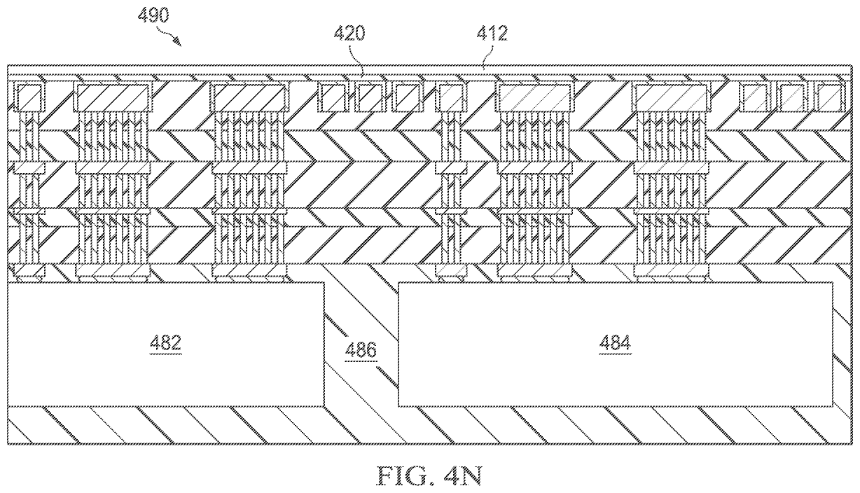

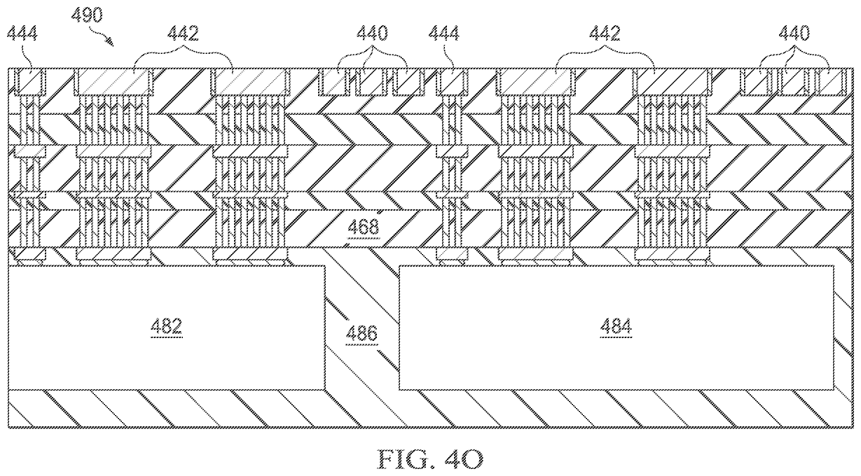

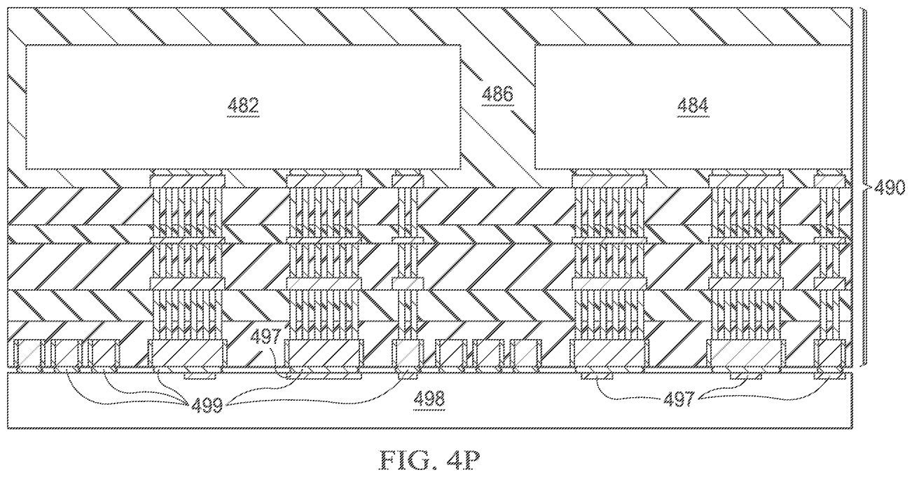

FIGS. 4A-4P illustrate an example process for constructing an IC package interposer configured for back-side attachment to a package substrate, without TSV or wire-bonding connection between the interposer and package substrate, according to one example embodiment.

First, as shown in FIG. 4A, a base silicon wafer 402 is constructed with a double layer of porous silicon (Si) 404 over a bulk silicon region e.g., according to process 300 discussed above with respect to FIG. 3. The double layer of porous Si 404 may include two layers of porous silicon having different measures of porosity, indicated as (a) Si layer 410 with porosity X and (b) Si layer 412 with porosity Y, which defines a planar interface 414 between Si layer 410 and Si layer 412 having an elevated level of stress, which facilitates a splitting of Si layer 410 from Si layer 412 at interface 414, as discussed below with respect to FIG. 4M.

As shown in FIG. 4B, a dielectric barrier layer 420 may be formed over the porous silicon double layer 404, particularly over Si layer 412. In an exemplary embodiment dielectric barrier layer 420 is formed directly on Si layer 412. The dielectric barrier layer 420 may comprise any material suitable to prevent interaction between porous Si and metals, for example, SiN, SiC, or SiO₂. The dielectric barrier layer 420 may be subsequently removed, as discussed below with respect to FIG. 4O.

As shown in FIG. 4C, a dielectric region 422 including one or more dielectric layers may be formed over the dielectric barrier layer 420. For example, the dielectric region 422 may include a combination of any of SiN, SiO₂, SiON, SiC, and/or other suitable dielectric material(s).

Referring next to FIG. 4D, a photomask (not shown) may be formed and patterned over the dielectric region 422 and an etch may be performed through openings in the photomask to define various openings (voids) in the dielectric region 422, using known photolithography and etch techniques, which exposes surface areas of dielectric barrier layer 420. The etched dielectric region openings may include openings for forming various types of back-side structures, for example, openings 430 for forming stress relief structures, openings 432 for forming contact pads, openings 434 for forming die seal elements, openings for forming reinforcement structures, stress relief voids, solder-assist voids and/or any openings for forming any other suitable components.

Referring next to FIG. 4E, a barrier metal, e.g., Ta/TaN or Ti/TiN, may be deposited over the structure and extending into the dielectric region openings 430, 432, 434 to form a barrier metal layer 438 covering the exposed surface areas of dielectric barrier layer 420 within each dielectric region opening. A single damascene process may then be performed to fill the dielectric region openings 430, 432, 434 with copper or other suitable metal to define various back-side (bottom-side) elements, in this example, stress relief structures 440, contact pads 442, and a die seal element 444. A chemical mechanical planarization (CMP) may be performed to remove the barrier metal (e.g., Ta/TaN) and fill metal (e.g., copper) extending outside the dielectric region openings 430, 432, 434, to thereby complete the single damascene process.

As shown in FIG. 4F, a reverse passivation region 448 may be formed, e.g., by depositing a mixture of oxides 450, followed by a chemical mechanical planarization (CMP), followed by depositing an SiON layer 452.

As shown in FIG. 4G, single damascene deep vias 454, 456 may be formed, e.g., using copper or tungsten, down to selected back-side elements formed in the dielectric region 422, e.g., contact pads 442 and die seal element 444. In some embodiments, redundant vias may be formed to contact a common back-side element (e.g., a particular contact pad 442) to provide reduced or optimized resistance.

As shown in FIG. 4H, a redistribution metal layer 460 (“Metal 1” layer) may be formed, e.g., using aluminum or copper technology. Redistribution metal layer 460 may include metal elements in contact with the vias 454, 456 formed as shown in FIG. 4G.

As shown in FIG. 4I, additional redistribution metal layer(s) 470 may be formed between additional dielectric layer(s), e.g., oxide layers and/or low-k films, and connected to each other by additional single damascene deep vias 464, 456 extending though the dielectric layer(s). Front-side (top-side) pads 474, 476 may then be formed (e.g., using copper or aluminum) on an exposed dielectric layer (e.g., SiON) 468 on top of the structure. Front-side pads 474, 476 may be formed in contact with respective vias 454, 456, to thereby provide a conductive connection between back-side elements (e.g., contact pads 442 and die seal elements 444) and respective front-side pads 474, 476.

As discussed above, in the implementation shown in FIGS. 4G-4I, vias 454, 456, metal layers 460, 470, and front-side pads 474, 476 may be formed as single damascene structures. In other embodiments, one, some, or all of such metal structures may be formed by a dual damascene process. For example, each respective metal layer 460, 470, or 464/476 may be formed together with underlying vias 454, 456 using a dual damascene process.

As shown in FIG. 4J, solder pillars 478, 480 may be formed on each front-side pad 474, 476.

As shown in FIG. 4K, one or more dies 482, 484 may be mounted to the interposer by soldering each die to selected front-side pads 474, 476 utilizing solder pillars 478, 480, respectively.

As shown in FIG. 4L, the wafer including dies 482, 484 may be encapsulated with resin or other suitable encapsulation material 486, e.g., using any known spin-on, aerosol, or molding technique. In some embodiments, the encapsulation process may include underfill.

As shown in FIG. 4M, the package structure may be inverted and the porous silicon double layer 404 may be split, e.g., using process 300 described above. For example, a water jet may be used to split the first porous Si layer 410 and the bulk Si carrier wafer 402 away from the second porous Si layer 412, e.g., facilitated by the elevated-stress interface 414 (shown in FIG. 4A) defined by the Si porosity difference between the first and second porous Si layers 410, 412. In some embodiments, after removal of the base silicon wafer 402, the encapsulation 486 formed at FIG. 4L is sufficient to physically support the remaining interposer structure, indicated at 490, for subsequent processing steps, without requiring a carrier wafer or other physical support structure.

As shown in FIG. 4N, the porous Si layer 410 and bulk Si carrier wafer 402, separated by the process as discussed above, may be removed and discarded or recycled.

As shown in FIG. 4O, the remaining porous Si layer 412, along with underlying dielectric barrier layer 420, and upper portions of barrier metal 438 may be etched or otherwise removed to expose the stress relief structures 440, contact pads 442 and die seal elements 444 (collectively, back-side pads). After the removal process to expose the back-side pads (i.e. stress relief structures 440, contact pads 442 and die seal elements 444), the interposer 490 is now configured for back-side attachment to a package substrate or other structure, for example by direct connection of the back-side pads stress relief structures 440, contact pads 442 and die seal elements 444 to respective structures in the package substrate, or by solder-ball attachment at the back-side pads stress relief structures 440, contact pads 442 and die seal elements 444.

As shown in FIG. 4P, the interposer structure 490 with mounted and encapsulated dies 482, 484 may be back-side mounted to a package substrate 498, e.g., by solder-ball bonding 499 the interposer back-side pads, i.e., stress relief structures 440, contact pads 442 and die seal elements 444 , to respective pads or other conductive structures 497 provided in the package substrate 498. As discussed above, the interposer structure 490 does not require TSV. In contrast to TSV, the size of back-side pads, i.e., stress relief structures 440, contact pads 442 and die seal elements 444 can be scaled with lithography to much smaller dimensions than TSV structures.

As discussed above, dies 482, 484 are mounted to the interposer front-side contacts 474 (FIG. 4K), and encapsulated by encapsulation material 486 (FIG. 4L), prior to splitting the porous silicon double layer 404 (FIG. 4M). In an alternative embodiment, the porous silicon double layer 404 may be split, e.g., using the techniques disclosed herein, prior to mounting dies 482, 484 to interposer front-side contacts 474 and encapsulating the mounted dies 482, 484.

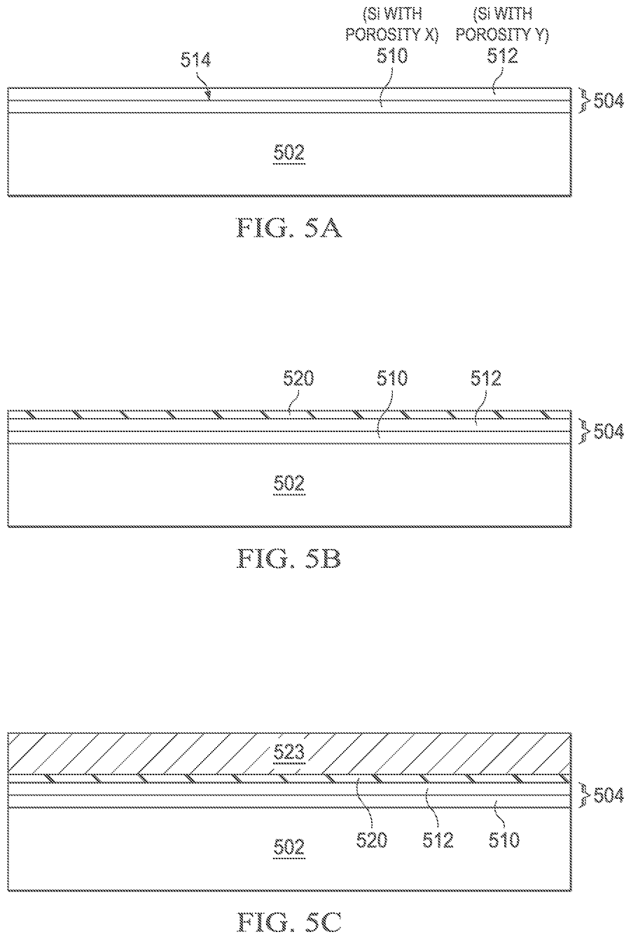

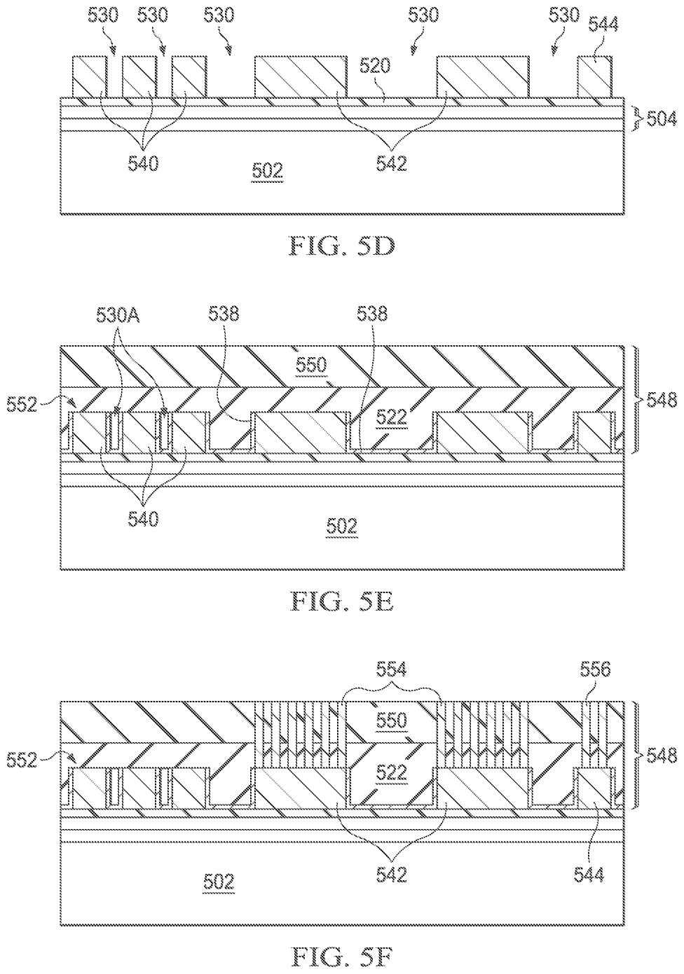

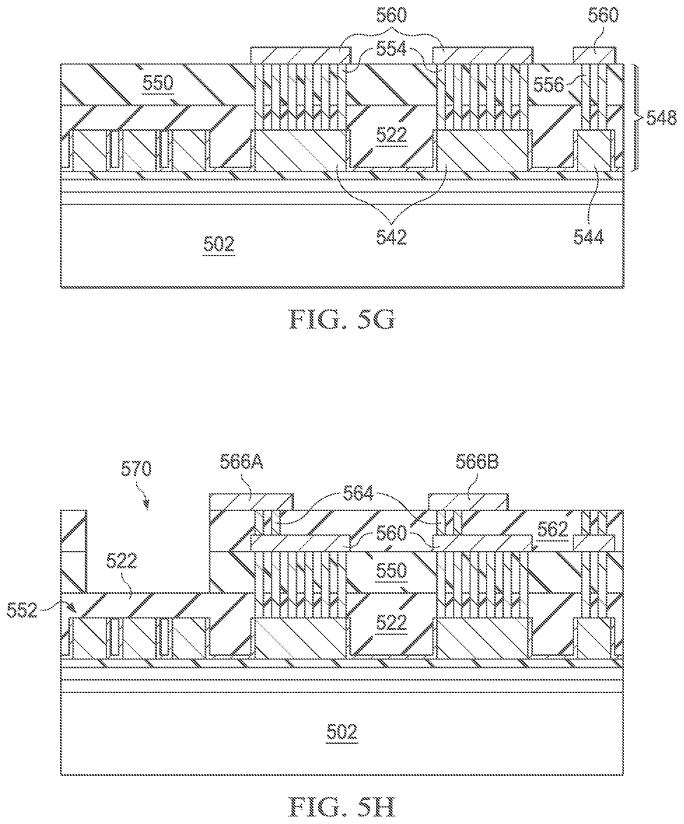

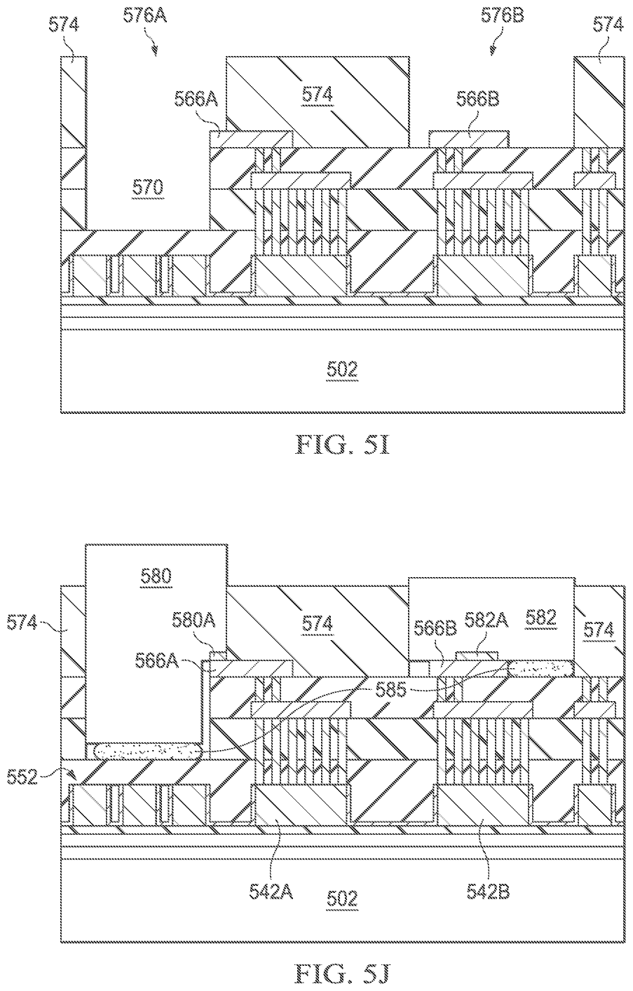

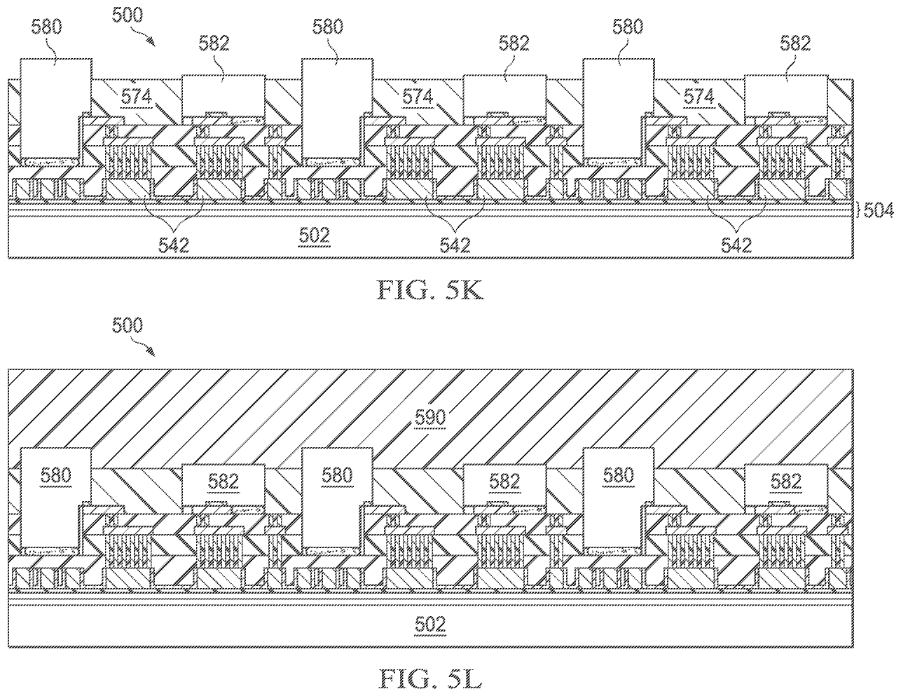

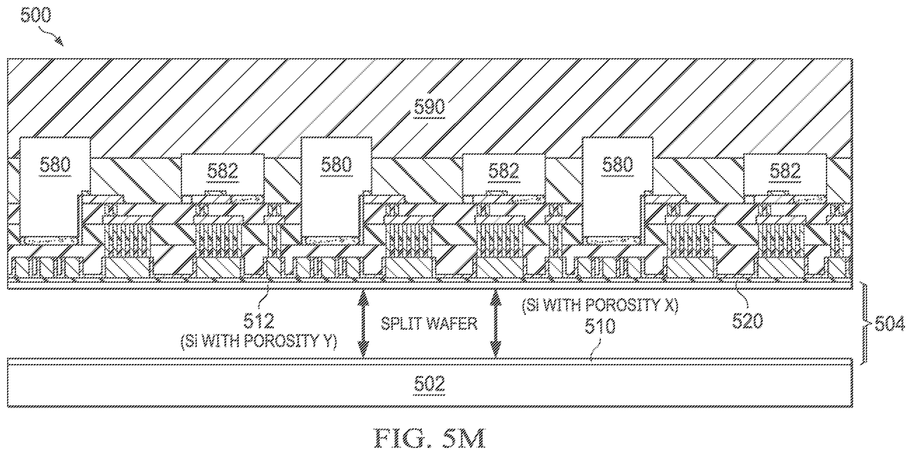

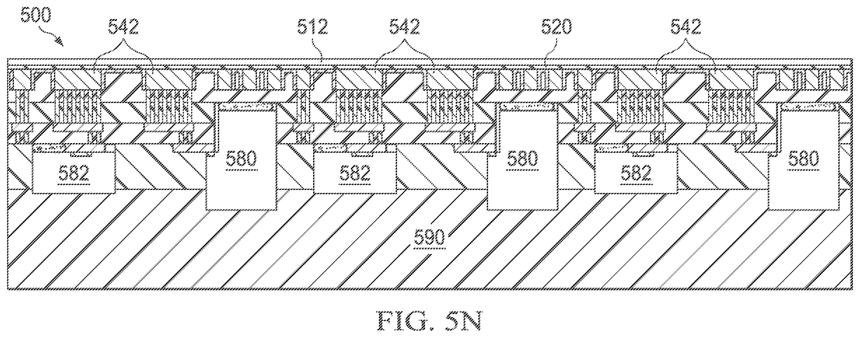

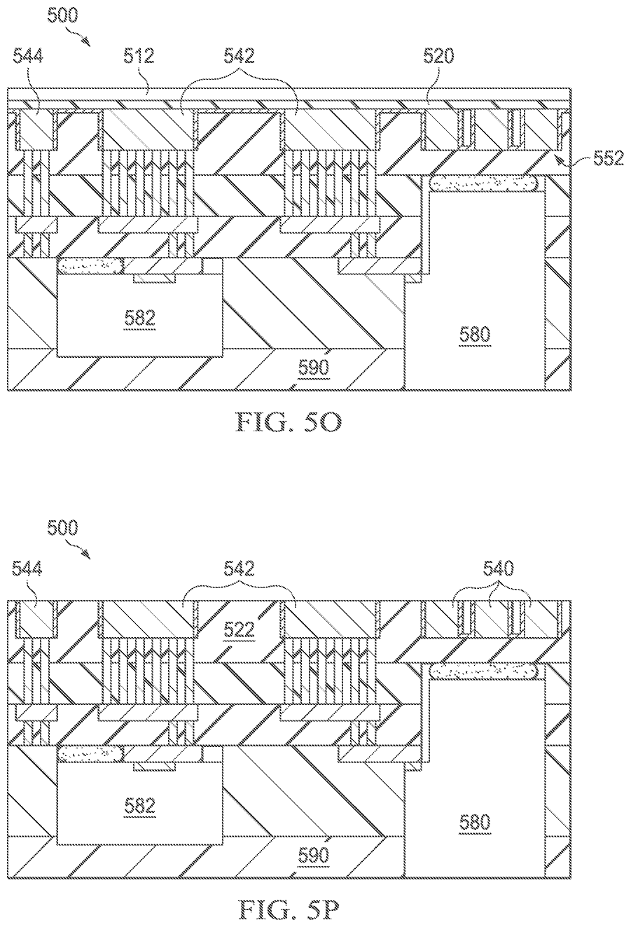

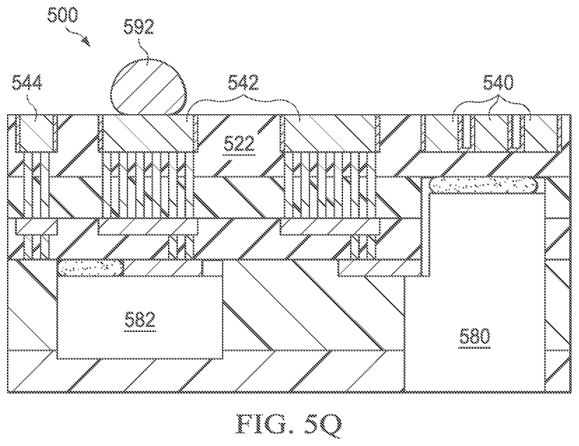

FIGS. 5A-5Q illustrates an example embodiment for constructing an example mixed-orientation multi-die (MOMD) package interposer configured for back-side attachment to a package substrate, without TSV or wire-bonding connection between the interposer and package substrate, according to one example embodiment.

First, as shown in FIG. 5A, a base silicon wafer 502 is constructed with a double layer of porous silicon (Si) 504 over a bulk silicon region, e.g., according to process 300 discussed above with respect to FIG. 3. The double layer of porous Si 504 may include two layers of porous silicon having different measures of porosity, indicated as (a) Si layer 510 with porosity X and (b) Si layer 512 with porosity Y, which defines a planar interface 514 between Si layer 510 and Si layer 512 having an elevated level of stress, which facilitates a splitting of Si layer 510 from Si layer 512 at interface 514, as discussed below with respect to FIG. 5M.

As shown in FIG. 5B, a dielectric barrier layer 520 may be formed over the porous silicon double layer 504. The dielectric barrier layer 520 may comprise any material suitable to prevent interaction between porous Si and metals, for example, SiN, SiC, or SiO₂. The dielectric barrier layer 520 may be subsequently removed, as discussed below with respect to FIG. 5P.

As shown in FIG. 5C, a pad metal stack 523 is formed over the dielectric barrier layer 520. In one embodiment, forming the pad metal stack 523 may include depositing a base layer of TiN or inert metal, followed by depositing a thick (e.g., greater than 2 μm) aluminum pad. This pad metal stack 523 can also be used as a redistribution layer and may be patterned to form stress relief structures.

As shown in FIG. 5D, the pad metal stack 523 is patterned and etched (using known metal etch techniques) to expose surface areas of dielectric barrier layer 520 and to form metal stack openings 530 that define a plurality of discrete metal structures, e.g., including one or more contact pads 542, stress relief structures 540, die seal structures 544, and/or any other type(s) of metal structures.

Referring next to FIG. 5E, a barrier metal, e.g., Ta/TaN or Ti/TiN, may be deposited over the structure and extending into the metal stack openings 530 to form a barrier metal layer 538 covering the exposed surface areas of dielectric barrier layer 520 within each metal stack opening 530.

After depositing the barrier layer 538, a reverse passivation region 548 may be formed. First, an oxide mixture 522 may be deposited to fill the metal stack openings 530 between metal structures, e.g., contact pads 542, stress relief structures 540, and/or die seal structures 544. In one embodiment, the deposited oxide mixture 522 and the deposition process are selected and/or tuned to define or ensure a non-conformal deposition of oxide mixture 522 such that the oxide mixture 522 fills metal stack openings 530 but does not fill the narrower metal stack openings 530 between adjacent stress relief structures 540, to thereby define open voids 530A forming part of the stress relief system. For example, the deposition rate (e.g., a high rate) and/or pressure in deposition chamber (e.g., within a selected range) may be controlled to define a highly non-conformal deposition of oxide mixture 522 that does not flow into the narrow metal stack openings 530. In some embodiments, metal stack openings 530 (after depositing barrier layer 538) may have an opening width of less than 200 nm, e.g., in the range of 60-200 nm, while other openings 530 and remaining structures (e.g., contact pads 542) may have a lateral width of at least 1 μm, e.g., in the range of 1-100 μm.

In some embodiments, the oxide mixture 522 may comprise a mixture of SiO₂ materials, which may be deposited using a plasma-enhanced CVD (PE-CVD) process, which may or may not involve high density plasma (HDP). In one example embodiment, a process such as a SEQUEL® express CVD process by Novellus Systems Inc. having a headquarters in San Jose, CA and owned by Lam Research Corporation having a headquarters in Fremont, CA may be utilized. In some embodiments, the deposition process may be adjusted or optimized to further increase the non-conformal nature of the deposition, to further ensure the formation of open voids 530A.

After depositing the oxide mixture 522, a CMP may be performed, followed by deposition of SiON layer 550, as shown in FIG. 5E. In some embodiments, the SiON layer 550 may be relatively thick, e.g., greater than 2 μm, for low stress and good adhesion properties. The combination of oxide mixture 522 and SiON layer 550 forms reverse passivation region 548.

As shown in FIG. 5E, the stress relief structures 540 and open voids 530A formed as described above may collectively define a stress relief system 552.

Next, as shown in FIG. 5F, single damascene deep vias 554, 556 may be formed through the reverse passivation region 548, e.g., using copper or tungsten, down to selected back-side elements, e.g., contact pads 542 and die seal element 544. In some embodiments, redundant vias may be formed to contact a common back-side element (e.g., a particular contact pad 542) to provide reduced or optimized resistance.

As shown in FIG. 5G, a first metal layer 560 (“Metal 1” layer) of the MOMD package may be formed on the SiON layer 550, e.g., using aluminum or copper technology. Metal 1 layer 560 may include metal elements in contact with the vias 554, 556 formed as shown in FIG. 5F.

As shown in FIG. 5H, an additional oxide layer 562 may be deposited, followed by formation of vias 564, and formation of front-side (top-side) contact pads 566A, 566B (e.g., comprising an Al-Sn alloy) coupled to Metal 1 elements 560 by vias 564. In addition, at least one VMD trench 570 may be etched, for receiving a vertically-mounted die (VIVID) as shown in FIG. 5J. As shown, a VMD trench 570 may be aligned over a stress relief system 552, e.g., to manage physical stress caused by mounting a VMD in the VMD trench 570. In some embodiments, additional trenches may be etched, e.g., for stress relief structures.

As shown in FIG. 5I, a polyimide layer may be formed, patterned, and etched to define die support/guide structures 574 configured to physically guide the mounting of one or more dies to the MOMD package interposer and/or physically support such die(s) once mounted. In this example, polyimide structures 574 define (a) a VMD opening 576A aligned over VMD trench 570 to collectively define an opening for receiving a VMD and (b) an HMD opening 576B for receiving an HMD. As shown, a first front-side contact pad 566A is exposed in the VMD opening 576A, and a second front-side contact pad 566B is exposed in the HMD opening 576B.

As shown in FIG. 5J, a VMD 580 is mounted vertically in the VMD opening 576A and extending down in to the VMD trench 570, such that a conductive contact 580A, connected to electronic circuitry in VIVID 580, comes into contact with the first front-side contact pad 566A, which provides a conductive connection from back-side contact pad 542A to the electronic circuitry in VMD 580. In addition, an HMD 582 is mounted horizontally in the HMD opening 576B, such that a conductive contact 582A, connected to electronic circuitry in HMD 582, comes into contact with the second front-side contact pad 566B, which provides a conductive connection from back-side contact pad 542B to the electronic circuitry in VMD 582. In one embodiment, an underfilm 585 may be deposited in VMD trench 570 and HMD opening 576B to physically support or cushion mounted VMD 580 and HMD 582.

FIG. 5K shows a zoomed-out wafer level view of the MOMD package interposer 500, including multiple VMDs 580 and HMDs 582, each conductively connected to at least one respective back-side contact pad 542 through respective metal layer structures and conductive vias.

Next, as shown in FIG. 5L, the MOMD package interposer 500 including mounted VMDs 580 and HMDs 582 may be encapsulated with a polymer or other suitable package encapsulation material 590.

As shown in FIG. 5M, the porous silicon double layer 504 may be split, e.g., using process 300 described above. For example, a water jet may be used to split the first porous Si layer 510 and the bulk Si carrier wafer 502 away from the second porous Si layer 512, e.g., facilitated by the elevated-stress interface 514 (shown in FIG. 5A) defined by the Si porosity difference between the first and second porous Si layers 510, 512.

As shown in FIG. 5N, the porous Si layer 510 and bulk Si carrier wafer 502, separated by the process as discussed above, may be removed, discarded, or recycled. The remaining MOMD package interposer 500 may be inverted, such that the second porous Si layer 512 is on top of the structure. In some embodiments, the inverted MOMD package interposer 500 may be mounted on a carrier wafer or other physical support structure. In other embodiments, the encapsulation 590 formed at FIG. 5L is sufficient to physically support the remaining MOMD package interposer 500 for subsequent processing steps, without requiring a carrier wafer or other physical support structure.

FIG. 5O shows a zoomed-in view of a portion of the inverted MOMD package interposer 500, with the second porous Si layer 512 on top, as discussed above.

As shown in FIG. 5P, the remaining porous Si layer 512, along with underlying dielectric barrier layer 520, and upper portions of barrier metal 538 may be etched or otherwise removed to expose the back-side pads, i.e. contact pads 542, stress relief structures 540, and/or die seal structures 544. After the removal process to expose the back-side pads contact pads 542, stress relief structures 540, and/or die seal structures 544, the MOMD package interposer 500 is now configured for back-side attachment to a package substrate or other structure, for example by direct connection of the back-side pads, i.e. contact pads 542, stress relief structures 540, and/or die seal structures 544 to respective structures in the package substrate, or by solder-ball attachment at the back-side pads, i.e. contact pads 542, stress relief structures 540, and/or die seal structures 544. For example, FIG. 5Q shows an example solder ball 592 formed on a selected back-side contact pad 542 connected to a VMD 582.

As discussed above, dies 582, 584 are mounted to the interposer front-side contact pads 566A, 566B (FIG. 5J), and encapsulated by encapsulation material 590 (FIG. 5L), prior to splitting the porous silicon double layer 504 (FIG. 5M). In an alternative embodiment, the porous silicon double layer 504 may be split, e.g., using the techniques disclosed herein, prior to mounting dies 582, 584 to interposer front-side contact pads 566A, 566B and encapsulating the mounted dies 582, 584.

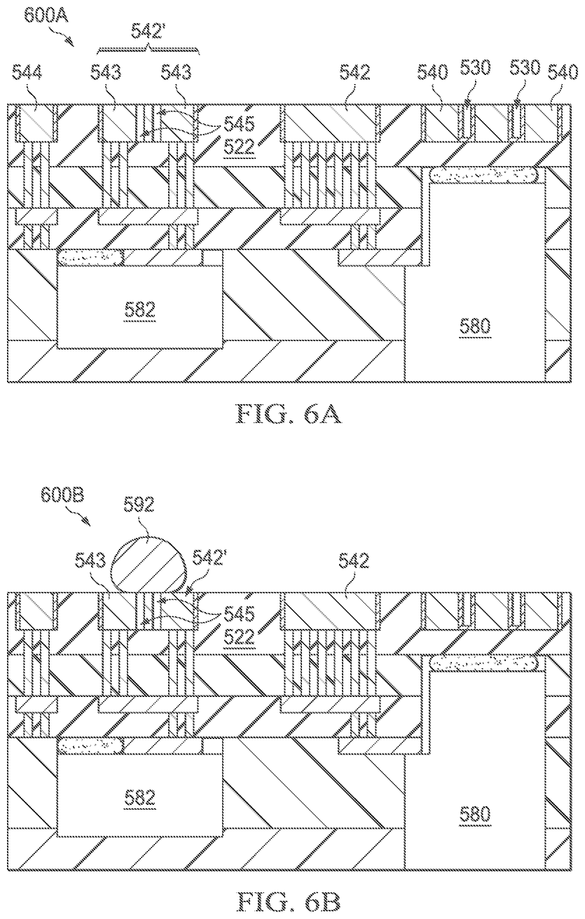

FIGS. 6A-6B illustrate an alternative to the embodiment shown in FIGS. 5A-5Q, wherein voids are formed in back-side contact pads, which may facilitate solder-ball attachment or direct attachment of the contact pads to a package substrate, according to one example embodiment. FIG. 6A shows an MOMD package interposer 600A similar to MOMD package interposer 500 discussed above, but including a back-side contact pad 542′ formed with open voids 545 between metal portions 543. FIG. 6B shows an example solder ball 592 formed on the back-side contact pad 542′, according to one example implementation.

1. A method of forming an integrated circuit (IC) package interposer configured for back-side attachment, comprising:
forming a base silicon wafer including a porous silicon double layer over a bulk silicon region, the porous silicon double layer including a first porous silicon layer having a first porosity adjacent a second porous silicon layer having a second porosity different than the first porosity;
forming an interposer over the porous silicon double layer, the interposer including:
back-side contacts on a back side of the interposer;
front-side contacts on a front side of the interposer; and
conductive structures extending through a vertical thickness of the interposer to connect selected back-side contacts with selected front-side contacts;
splitting the porous silicon double layer to separate the first porous silicon layer from the second porous silicon layer, and removing the separated first porous silicon layer and bulk silicon region; and
after splitting the porous silicon double layer, removing at least the second silicon layer to expose the back-side contacts, the exposed back-side contacts configured for attachment to a package substrate or other structure.

2. The method of claim 1, further comprising using the exposed back-side contacts to back-side mount the IC package interposer to the package substrate or other structure.

3. The method of claim 2, comprising soldering the exposed back-side contacts to the package substrate or other structure.

4. The method of claim 2, comprising direct attaching the exposed back-side contacts to the package substrate or other structure.

5. The method of claim 1, further comprising mounting at least one die to at least one front-side contact.

6. The method of claim 5, further comprising mounting the at least one die to the at least one front-side contact and encapsulating the at least one mounted die prior to splitting the porous silicon double layer.

7. The method of claim 5, further comprising mounting at least one die to at least one front-side VMD contact in a vertical orientation and mounting at least one die to at least one front-side HMD contact in a horizontal orientation.

8. The method of claim 1, wherein splitting the porous silicon double layer to separate the first porous silicon layer from the second porous silicon layer comprises using a water jet to separate the first porous silicon layer from the second porous silicon layer.

9. The method of claim 1, wherein forming the interposer comprises forming a plurality of vias and at least one metal layer between the back-side contacts and front-side contacts to define the conductive structures extending through the vertical thickness the interposer to connect selected back-side contacts with selected front-side contacts.

10. A method of forming an integrated circuit (IC) package interposer configured for back-side attachment, comprising:
performing an anodizing process on a base silicon wafer to form a multi-layer silicon region including a first porous silicon layer having a first porosity adjacent a second porous silicon layer having a second porosity different than the first porosity;
forming an interposer over the multi-layer silicon region, the interposer including:
back-side contacts on a back side of the interposer;
front-side contacts on a front side of the interposer; and
conductive structures extending through a vertical thickness of the interposer to connect selected back-side contacts with selected front-side contacts;
mounting at least one die to at least one of the front-side contacts;
splitting the multi-layer silicon region to separate the first porous silicon layer from the second porous silicon layer; and
after splitting the multi-layer silicon region, removing at least the second silicon layer to expose the back-side contacts, the exposed back-side contacts configured for attachment to a package substrate or other structure.

11. The method of claim 10, further comprising using the exposed back-side contacts to back-side mount the IC package interposer to the package substrate or other structure.

12. The method of claim 11, comprising soldering the exposed back-side contacts to the package substrate or other structure.

13. The method of claim 11, comprising direct attaching the exposed back-side contacts to the package substrate or other structure.

14. The method of claim 10, further comprising encapsulating the at least one mounted die prior to splitting the porous silicon double layer.

15. The method of claim 10, wherein mounting at least one die to at least one of the front-side contacts comprises mounting at least one die to at least one front-side VMD contact in a vertical orientation and mounting at least one die to at least one front-side HMD contact in a horizontal orientation.

16. The method of claim 10, wherein splitting the multi-layer silicon region to separate the first porous silicon layer from the second porous silicon layer comprises using a water jet to separate the first porous silicon layer from the second porous silicon layer.

17. The method of claim 10, wherein forming the interposer comprises forming a plurality of vias and at least one metal layer between the back-side contacts and front-side contacts to define the conductive structures extending through the vertical thickness of the interposer to connect selected back-side contacts with selected front-side contacts.

18. An integrated circuit (IC) package, comprising:
an IC package substrate; and
an interposer, comprising:
back-side contact pads on a back side of the interposer;
front-side contact pads on a front side of the interposer; and
conductive structures extending through a vertical thickness of the interposer to connect selected back-side contact pads with selected front-side contact pads;
at least one die mounted to the front-side contact pads;
wherein the interposer is back-side attached to an IC package substrate by the back-side contact pads.

19. The IC package of claim 18, wherein the interposer includes no wafer substrate.

20. The IC package of claim 18, wherein the interposer includes no through-silicon vias (TSVs).
